(19) United States
(12) Patent Application Publication
(10) Pub. No.: US 2015/0263118 A1
(43) Pub. Date: Sep. 17, 2015

(54) SEMICONDUCTOR MEMORY DEVICE AND METHOD OF MANUFACTURING THE SAME

(71) Applicant: Kabushiki Kaisha Toshiba, Minato-ku (JP)

(72) Inventors: Takeshi KAMIGAICHI, Yokkaichi-shi (JP); Atsushi MURAKOSHI, Yokkaichi-shi (JP)

(73) Assignee: Kabushiki Kaisha Toshiba, Minato-ku (JP)

(21) Appl. No.: 14/465,987

(22) Filed: Aug. 22, 2014

Related U.S. Application Data
(60) Provisional application No. 61/952,730, filed on Mar. 13, 2014.

(51) Int. Cl. H01L 29/49; H01L 29/423; H01L 29/66; H01L 29/06; H01L 21/285; H01L 27/115; H01L 21/28; H01L 29/788; H01L 21/762

(52) U.S. Cl. CPC H01L 29/4916; H01L 29/7883; H01L 29/42324; H01L 29/66825; H01L 21/76224; H01L 21/28518; H01L 21/2855; H01L 27/11521; H01L 21/28273; H01L 29/0649

(57) ABSTRACT

A semiconductor memory device according to an embodiment comprises: a floating gate formed on a substrate via a tunnel insulating film; a gate electrode formed in a region including a region above the floating gate; and an inter-layer insulating film formed between the floating gate and the gate electrode, above and on a side of the floating gate. At least a part of a surface of the floating gate exposed to an inter-layer insulating film side has a silicide layer formed thereon.

### CROSS REFERENCE TO RELATED APPLICATION

This application is based on and claims the benefit of priority from prior U.S. Provisional Patent Application No. 61/952,730, filed on Mar. 13, 2014, the entire contents of which are incorporated herein by reference.

### FIELD

Embodiments described in the present specification relate to a semiconductor memory device and a method of manufacturing the same.

### BACKGROUND

In a nonvolatile semiconductor memory device such as a NAND type flash memory, a memory cell includes a control gate and a charge accumulation layer, and stores as data a magnitude of a threshold voltage of the memory cell that changes according to a charge accumulated in the charge accumulation layer. It is known that by setting a plurality of threshold voltages in the memory cell of the above-described semiconductor memory device, the semiconductor memory device is made capable of multi-level storage.

### BRIEF DESCRIPTION OF THE DRAWINGS

FIG. 1 is an overall block diagram of a semiconductor memory device according to a first embodiment.

FIG. 2 is a circuit diagram showing a detailed configuration of a memory cell array.

FIG. 3 includes schematic views showing threshold voltages of a memory cell during data write.

FIG. 4 is a cross-sectional schematic view showing a configuration of a memory cell of a general semiconductor memory device.

FIG. 5 is a schematic view showing a band structure in the memory cell of FIG. 4.

FIG. 6 is a cross-sectional schematic view showing a configuration of the memory cell of the semiconductor memory device according to the first embodiment.

FIG. 7 is a schematic view showing a band structure in the memory cell of FIG. 6.

FIG. 8 is a (first) view showing a method of manufacturing the semiconductor memory device according to the first embodiment.

FIG. 9 is a (second) view showing the method of manufacturing the semiconductor memory device according to the first embodiment.

FIG. 10 is a (third) view showing the method of manufacturing the semiconductor memory device according to the first embodiment.

FIG. 11 is a (fourth) view showing the method of manufacturing the semiconductor memory device according to the first embodiment.

FIG. 12 is a (fifth) view showing the method of manufacturing the semiconductor memory device according to the first embodiment.

FIG. 13 is a (sixth) view showing the method of manufacturing the semiconductor memory device according to the first embodiment.

FIG. 14 is a (seventh) view showing the method of manufacturing the semiconductor memory device according to the first embodiment.

FIG. 15 is a cross-sectional schematic view showing a configuration of a memory cell of a semiconductor memory device according to a second embodiment.

FIG. 16 is a cross-sectional schematic view showing a configuration of a memory cell of a semiconductor memory device according to a third embodiment.

### DETAILED DESCRIPTION

A semiconductor memory device according to an embodiment comprises: a floating gate formed on a substrate via a tunnel insulating film; a gate electrode formed in a region including a region above the floating gate; and an inter-layer insulating film formed between the floating gate and the gate electrode, above and on a side of the floating gate. At least a part of a surface of the floating gate exposed to an inter-layer insulating film side has a silicide layer formed thereon.

Embodiments will be described in detail below with reference to the drawings.

### First Embodiment

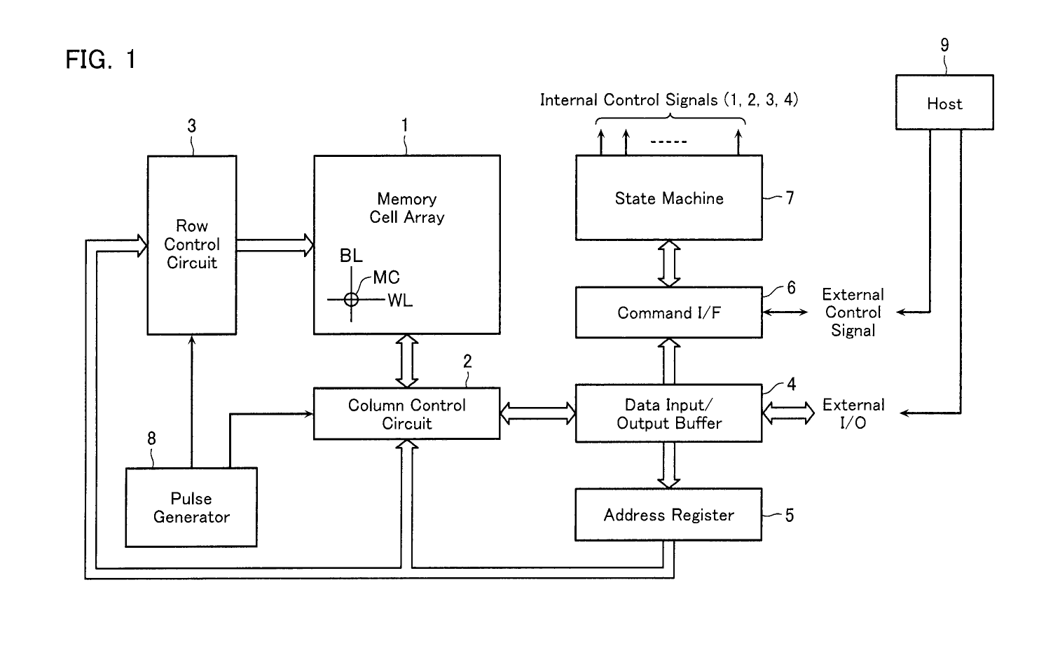

First, a first embodiment will be described with reference to FIGS. 1 to 14. FIG. 1 is a block diagram showing a configuration of a nonvolatile semiconductor memory device according to the first embodiment. The present semiconductor memory device is a NAND type flash memory adopting a four-level storage system. The present semiconductor memory device comprises a memory cell array 1 having a plurality of data-storing memory cells MC disposed in a matrix therein. The memory cell array 1 includes a plurality of bit lines BL and a plurality of word lines WL that intersect each other, and has the memory cell MC disposed at each of intersections of said bit lines BL and word lines WL. The memory cell MC has a stacked structure of a floating gate electrode which functions as a charge accumulation layer that accumulates a charge, and a control gate electrode which is connected to the word line WL. The memory cell MC is configured capable of electrically rewriting data by injection or release of charge into/from the floating gate electrode.

Connected to the memory cell array 1 are a column control circuit 2 for controlling a voltage of the bit line BL, and a row control circuit 3 for controlling a voltage of the word line WL. The column control circuit 2 reads data from the memory cell MC via the bit line BL and performs write of data to the memory cell MC via the bit line BL. The row control circuit 3 applies a voltage for write, read, and erase of data, to a gate electrode of the memory cell MC, via the word line WL.

Connected to the column control circuit 2 is a data input/output buffer 4. Data of the memory cell MC read by the column control circuit 2 is outputted to an external host 9 from a data input/output terminal (external I/O) via the data input/output buffer 4. Moreover, write data inputted to the data input/output terminal (external I/O) from the external host 9 is inputted to the column control circuit 2 via the data input/output buffer 4, and is written to a designated memory cell MC.

Connected to the data input/output buffer 4 are an address register 5 and a command I/F 6. The address register 5 outputs address information inputted from the data input/output buffer 4, to the column control circuit 2 and the row control circuit 3. The command I/F 6 is connected to a state machine 7 and the external host 9, and sends/receives a control signal between these blocks. Connected to the state machine 7 are the memory cell array 1, the column control circuit 2, the row control circuit 3, and the data input/output buffer 4. The state machine 7 generates an internal control signal for controlling the memory cell array 1, the column control circuit 2, the row control circuit 3, and the data input/output buffer 4, based on an external control signal inputted from the host 9 via the command I/F 6. The above-described various kinds of circuits including the column control circuit 2 and the row control circuit 3 function as a control circuit that controls a data write operation during data write to the later-described memory cell MC.

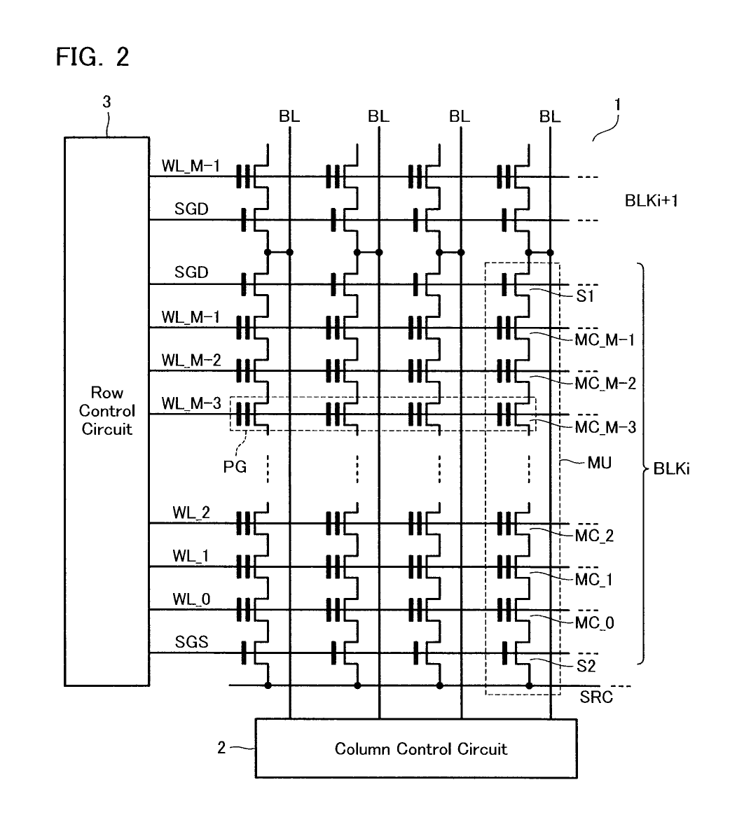

FIG. 2 is a circuit diagram showing a configuration of a part of the memory cell array 1 shown in FIG. 1. The memory cell array 1 includes a plurality of memory units MU. The memory unit MU is configured from M (for example, M=16) memory cells MC_0 to MC_M−1 connected in series, and a first select gate transistor S1 and a second select gate transistor S2 connected to the two ends of these series-connected memory cells MC_0 to MC_M−1. One end of the first select gate transistor S1 is connected to the bit line BL, and one end of the second select gate transistor S2 is connected to a source line SRC. That is, the memory cells MC are arranged in series sandwiched by a plurality of select transistors (S1 and S2), at a region of intersection of the word line WL and the bit line BL.

Word lines WL_0 to WL_M−1 are connected to the control gate electrodes of the memory cells MC_0 to MC_M−1. The plurality of memory units MU are arranged in a direction of formation of the word line WL, and form one block BLKi. In the memory cell array 1, erase of data is performed in a block BLK unit. Moreover, the plurality of memory cells MC commonly connected to one word line WL (reference symbol PG) forms one page or a plurality of pages. In the memory cell array 1, write and read of data is performed simultaneously on the memory cells along one word line.

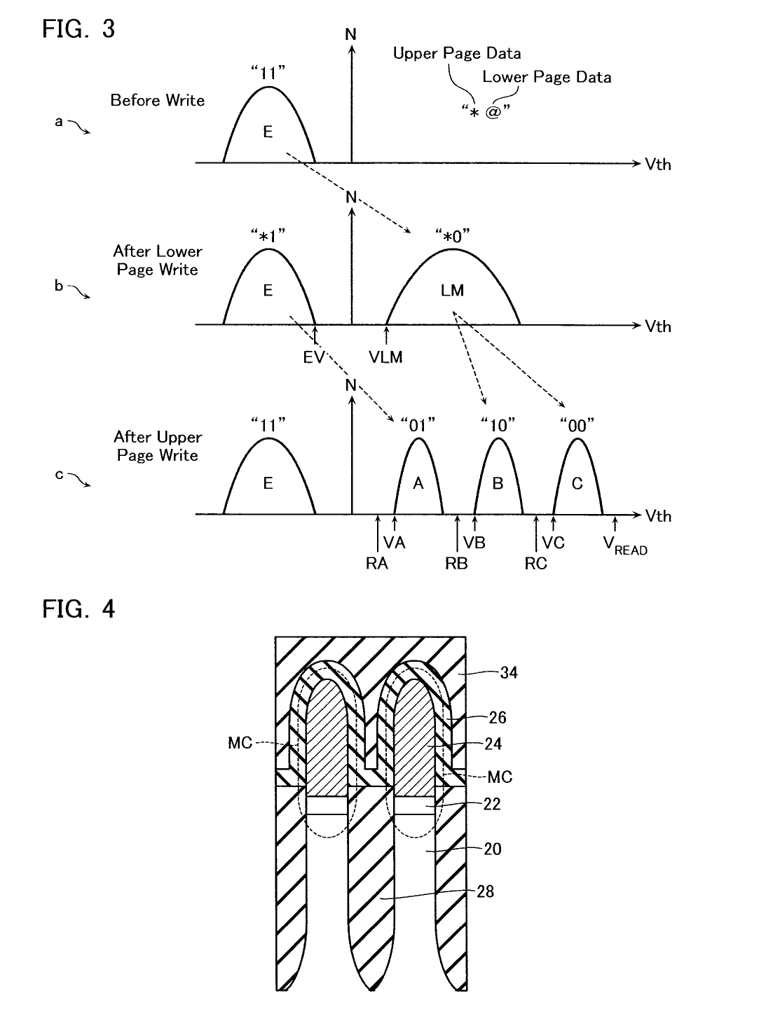

Next, an outline of a data storage system of the nonvolatile semiconductor memory device will be described. The nonvolatile semiconductor memory device is configured such that a threshold voltage of the memory cell MC can have four kinds of distributions. FIG. 3, in a to c thereof, includes views showing a relationship between change in a threshold voltage distribution of the memory cell MC and two-bit four-level data stored in the memory cell MC during data write of the nonvolatile semiconductor memory device. The four-level data are specified by, for example, a negative threshold voltage distribution (erase distribution) E having a lowest level of voltage level, and threshold voltage distributions A, B, and C having higher voltage levels than that of the threshold voltage distribution E. In the present embodiment, the threshold voltage distributions E, A, B, and C are assumed to correspond to data “11”, “01”, “10”, and “00”, respectively.

First, as shown in a of FIG. 3, before write, the memory cells included in the write-target block (refer to BLKi of FIG. 2) are all set to the erase state threshold voltage distribution (E) by data erase. This data erase is performed by, for example, applying a positive erase voltage (Vera, not illustrated in FIG. 3) to a well where the memory cell array 1 is formed, and setting a potential of all word lines WL of the selected block to 0 V, thereby releasing electrons from the floating gates of all memory cells MC.

Next, as shown in b of FIG. 3, some of the memory cells MC in the erase state (E) undergo a lower page write (Lower Page Program) that raises their threshold voltage to an intermediate voltage distribution (LM). Then, a verify operation for verifying completion of the lower page write is performed by setting a verify voltage to a voltage VLM and applying said voltage between the gate and the source of the memory cell MC. If the memory cell MC conducts due to the verify voltage VLM, then write fail (FAIL) is determined, and if the memory cell MC does not conduct due to the verify voltage VLM, then write pass (PASS) is determined. As a result, the threshold voltage of the memory cell MC that has undergone the lower page write rises and undergoes transition to the intermediate threshold voltage distribution (LM).

Next, as shown in c of FIG. 3, an upper page write (Upper Page Program) is performed that raises some of the memory cells MC in the erase state (E) to the threshold voltage distribution A and raises the memory cell MC in the intermediate voltage distribution (LM) to the threshold voltage distribution B or C. Then, similarly to in the case of the lower page write, a verify operation for verifying completion of the upper page write is performed by setting a verify voltage to, respectively, VA, VB, and VC and applying said voltage between the gate and the source of the memory cell MC. As a result, the threshold voltage of the memory cell MC that has undergone the upper page write rises and undergoes transition to any one of the threshold voltage distributions A, B, and C.

In the above data write operation, the selected word line to which one page of write-target memory cells MC are connected is provided with a write voltage VPGM (about 20 to 28 V), and another non-selected word line is provided with a write pass voltage Vpass (about 8 to 10 V). On that basis, depending on write data, the bit line electrically connected to the write-target memory cell MC is selectively provided with a ground voltage Vss (in the case of “0” write) and a power supply voltage VDD (in the case of “1” write). As a result, electrons are selectively injected into the floating gate of the memory cell MC.

In the case of “0” write that raises the threshold voltage, the ground voltage Vss provided to the bit line is transmitted to a channel of the NAND cell unit via the first select gate transistor S1 set to a conductive state. As a result, when the write voltage VPGM is provided, a tunnel current flows between the channel and the floating gate, and electrons are injected into the floating gate.

On the other hand, in the case of “1” write that does not raise the threshold voltage (write inhibit), the bit line is provided with the power supply voltage VDD. In this state, even if the power supply voltage VDD is provided to the first select gate transistor S1, the channel of the NAND cell unit is charged to VDD-Vt (Vt is the threshold voltage of the first select gate transistor S1) to be in a floating state. As a result, when the write voltage VPGM is provided, the cell channel is boosted by capacitive coupling, and electron injection into the floating gate does not occur.

During read of data, read voltages RA, RB, and RC which are voltages between upper limits and lower limits of each of the threshold voltage distributions E to C are applied between the gate and the source of the read-target selected memory cell MC. Moreover, a read pass voltage V_{READ} (refer to c of FIG. 3) which is larger than the upper limit of the threshold voltage distribution C is applied between the gate and the source of a non-read-target non-selected memory cell MC. The read pass voltage V_{READ} is a voltage that has a value larger than that of the upper limit of the threshold voltage distribution C and that enables the memory cell MC to be set to a conductive state irrespective of held data of the memory cell MC.

As described above, the threshold voltage distribution of the write-completed memory cell MC eventually becomes any one of E, A, B, and C (refer to c of FIG. 3). As previously mentioned, these threshold voltage distributions correspond to data “11(E)”, “01(A)”, “10(B)”, and “00(C)”, respectively. That is, two-bit data of one memory cell MC is configured from lower page data and upper page data, and when notated as data “*@”, “*” represents the upper page data, and “@” represents the lower page data.

FIG. 4 is a cross-sectional schematic view showing a configuration of a memory cell of a general semiconductor memory device. A memory cell MC is formed having a tunnel insulating film 22 and a floating gate stacked sequentially on a substrate 20. Formed between adjacent memory cells MC is a shallow trench isolation 28 (referred to below as “STI 28”) acting as an element isolation region. Formed in a region including an upper surface and a side surface of the floating gate 24 is an inter-layer insulating film 26. Formed above the inter-layer insulating film 26 is a gate electrode 34. A channel region positioned in a vicinity of a surface of the substrate 20 in the memory cell MC is electrically connected to the bit line BL shown in FIG. 2.

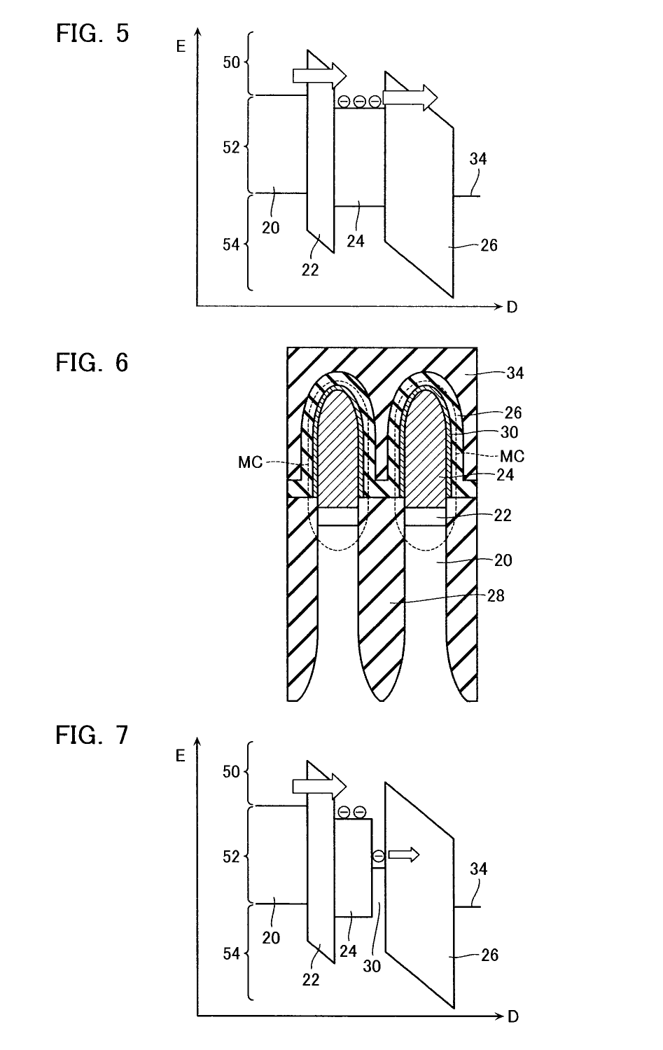

FIG. 5 is a schematic view showing a band structure in the memory cell of FIG. 4. The vertical axis E corresponds to energy and the horizontal axis D corresponds to position within the memory cell. Moreover, in FIG. 5, a region indicated by reference number 50 represents a conduction band, a region indicated by reference number 52 represents a forbidden band, and a region indicated by reference number 54 represents a valence band. As shown in FIG. 5, the tunnel insulating film 22 having a large width of forbidden band exists between the substrate 20 and the floating gate 24. Moreover, the inter-layer insulating film 26 having a large width of forbidden band exists between the floating gate 24 and the gate electrode 34. Two electronic barriers, namely the tunnel insulating film and the inter-layer insulating film 26, make it possible for leaking of electrons from inside the floating gate 24 to be suppressed and for a charge to be accumulated in the floating gate 24. Note that the gate electrode 34 is a conductor, hence the forbidden band 52 does not exist.

In the memory cell having the band structure shown in FIG. 5, a magnitude of the electronic barrier between the floating gate 24 and the inter-layer insulating film 26 is, for example, about 3 eV, and in some cases could not be said to be of sufficient magnitude. Therefore, sometimes, electrons leak to a gate electrode 34 side via the inter-layer insulating film 26 and the threshold voltage of the memory cell ends up lowering.

FIG. 6 is a cross-sectional schematic view showing a configuration of the memory cell of the semiconductor memory device according to the first embodiment. Similarly to in FIG. 4, the memory cell MC is formed having the tunnel insulating film 22 and the floating gate 24 stacked sequentially on the substrate 20. Employable in the substrate 20 is, for example, silicon (Si). Employable in the tunnel insulating film 22 is, for example, silicon oxide (SiO₂, or the like). Employable in the floating gate 24 is, for example, polysilicon.

Formed between adjacent memory cells MC is the STI 28 acting as an element isolation region. Employable in the STI 28 is, for example, silicon oxide. Formed in a region including a region above the floating gate 24 is the gate electrode 34. Employable in the gate electrode 34 is, for example, a metal material such as aluminum. In the present embodiment, the gate elect rode 34 is formed also between adjacent floating gates 24, that is, on a side of the floating gate 24.

Formed between the floating gate 24 and the gate electrode 34 is the inter-layer insulating film 26. Employable in the inter-layer insulating film. 26 is, for example, a silicon oxide film. In the present embodiment, the gate electrode 34 is formed above and to the side of the adjacent floating gates 24, hence the inter-layer insulating film 26 is formed on the upper surface and the side surface of the floating gate 24.

Now, formed on the surface of the floating gate 24 in FIG. 6 is a silicide layer 30 which is a metal layer that has been silicided. The silicide layer 30 is formed on the entire surface of the floating gate 24 exposed to an inter-layer insulating film 26 side, and has a configuration that the floating gate 24 and the inter-layer insulating film 26 are completely separated by the silicide layer 30. The silicide layer 30 may be configured to include a compound of at least one of ruthenium, nickel, titanium, tungsten, cobalt, and platinum, for example.

FIG. 7 is a schematic view showing a band structure in the memory cell of FIG. 6. Portions shared with FIG. 4 are assigned with identical reference symbols to those of FIG. 4, and a detailed description of such portions will be omitted. In FIG. 7, the silicide layer 30 is formed between the floating gate 24 and the inter-layer insulating film 26. The silicide layer 30 configures a region where there is almost no forbidden band 52, and the electronic barrier between the silicide layer 30 and the inter-layer insulating film 26 is increased compared to in FIG. 4. The magnitude of said electronic barrier is, for example, about 3 eV to 4 eV.

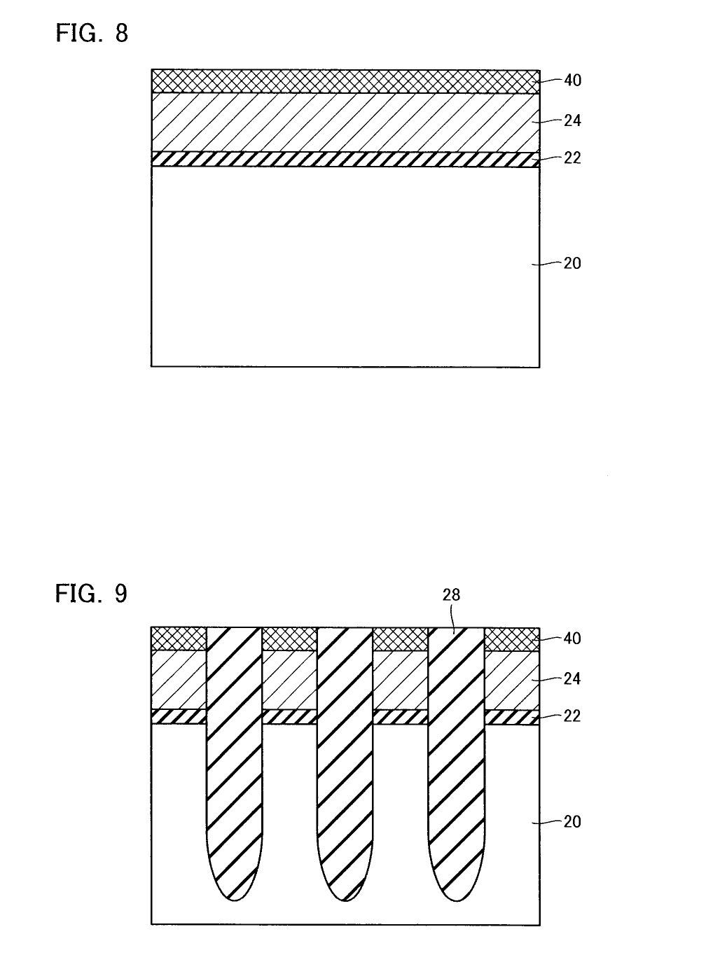

Next, a method of manufacturing the semiconductor memory device according to the first embodiment will be described using FIGS. 8 to 14. FIGS. 8 to 14 are cross-sectional schematic views showing the method of manufacturing, and for ease of display, a shape of the floating gate is changed from that in FIG. 6. First, as shown in FIG. 8, the tunnel insulating film 22, the floating gate 24, and a mask material 40 are stacked sequentially on the substrate 20. Next, as shown in FIG. 9, the mask material 40 undergoes patterning according to a shape of the memory cell, and etching is performed penetrating the floating gate 24 and the tunnel insulating film 22 to the substrate 20. Then, an insulator is filled into a concave portion formed by the etching, and the STI 28 is formed. Note that materials of each of members are as mentioned in the description of FIG. 6, and a detailed description of those materials will be omitted here.

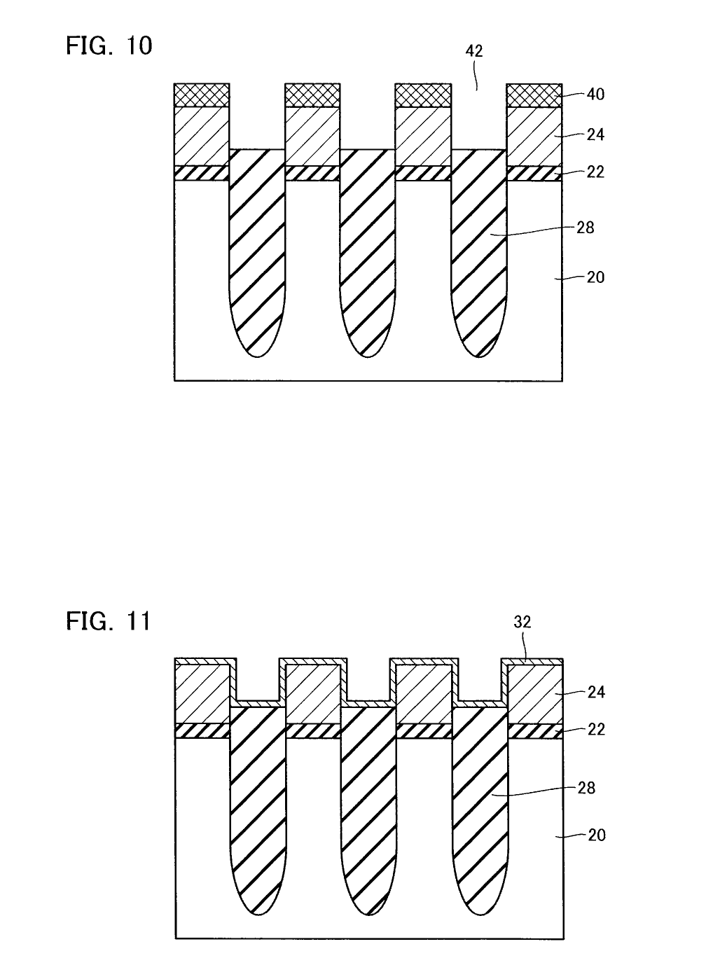

Next, as shown in FIG. 10, a part of the STI 28 is removed, and at least a part of the side surface of the floating gate 24 is exposed. Next, as shown in FIG. 11, the mask material 40 is peeled off, and a thin metal layer 32 is attached to the upper surface and the side surface of the floating gate 24 and an upper surface of the STI 28 (the entire upper surface of the semiconductor device). The metal layer 32 may be configured to include at least one of ruthenium, nickel, titanium, tungsten, cobalt, and platinum. Formation of the metal layer 32 can be performed by, for example, sputtering, but may also be performed by another method such as an ALD (Atomic Layer Deposition) method.

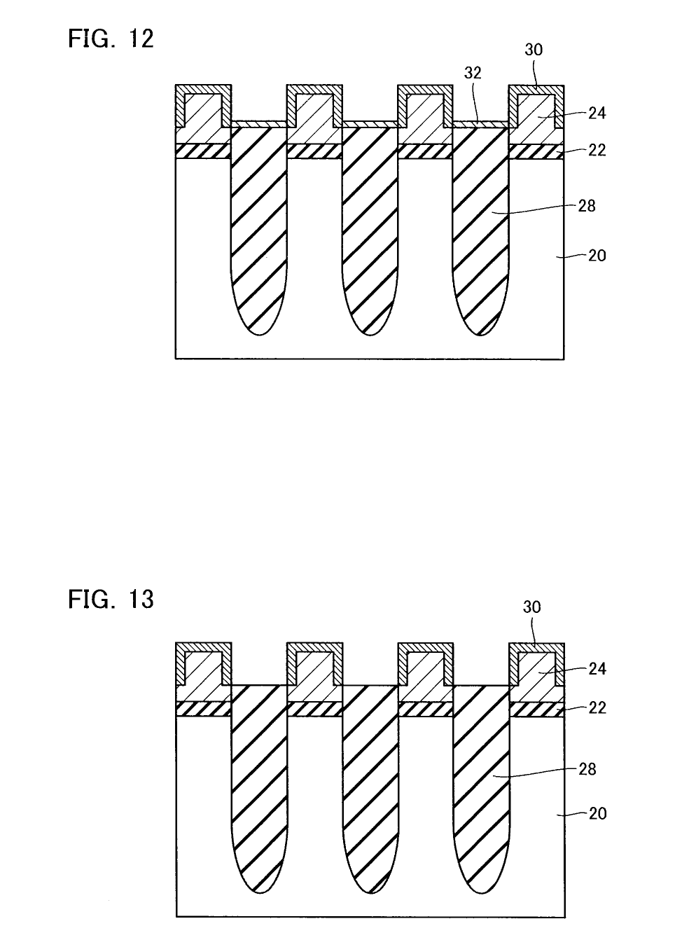

Next, as shown in FIG. 12, the metal layer 32 is reacted with the surface of the floating gate 24 to perform siliciding. The siliciding can be performed by, for example, employing a thermal anneal processing to mutually diffuse atoms of the metal layer 32 and atoms of the floating gate 24, but another method may also be employed. As a result, the entire region of the floating gate 24 exposed to outside has the silicide layer 30 formed thereon.

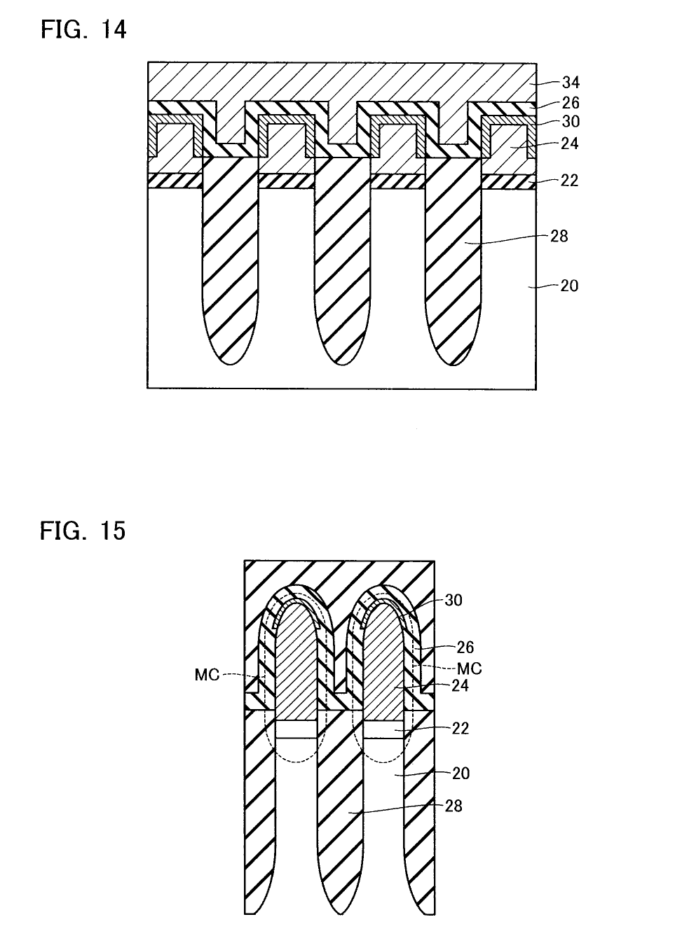

Next, as shown in FIG. 13, the metal layer 32 remaining on the surface of the STI 28 is removed. Then, as shown in FIG. 14, the inter-layer insulating film 26 is formed on the upper surfaces of the STI 28 and the silicide layer 30 (the entire upper surface of the semiconductor device), and the gate electrode is formed further thereon. The above processes result in the semiconductor memory device according to the first embodiment being completed.

Due to the semiconductor memory device according to the first embodiment, by trapping electrons in the silicide layer 30 (refer to FIG. 7), it is made possible to suppress leaking of electrons from the floating gate 24 via the inter-layer insulating film 26. As a result, lowering of the threshold voltage of the memory cell can be suppressed.

The silicide layer 30 can have its thickness set appropriately according to a pitch between floating gates, and so on, but is preferably configured to include, at a tip end (opposite side to the substrate 20) of the floating gate 24, a region in which siliciding is not performed. For example, the silicide layer 30 can be set to 5 nm or less, and in the case of being made thinner, may be set to 1 nm or less.

### Second Embodiment

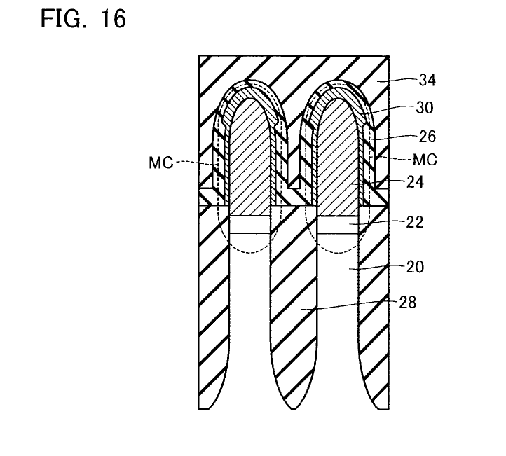

Next, a semiconductor memory device according to a second embodiment will be described using FIG. 15. FIG. 15 is a cross-sectional schematic view of the semiconductor memory device, portions shared with the first embodiment (FIG. 6) are assigned with identical reference symbols to those of the first embodiment, and a detailed description of such portions will be omitted.

As shown in FIG. 15, the second embodiment has a configuration in which the silicide layer 30 is formed only at the tip end of the floating gate 24. In order to obtain said configuration, it is only required, for example, that in a step of forming the metal layer 32 of FIG. 11, the metal layer 32 is selectively formed at the tip end of the floating gate 24 by sputtering, or the like.

An electric field in the floating gate 24 is concentrated at the tip end facing the gate electrode 34. Therefore, if the silicide layer 30 is formed in at least a region facing the gate electrode 34, then a band structure similar to that shown in FIG. 7 can be formed, and the previously-mentioned advantage of suppressing leakage of electrons can be displayed.

As described above, due to the semiconductor memory device according to the second embodiment, it is made possible to suppress leaking of electrons from the floating gate 24 via the inter-layer insulating film 26. As a result, lowering of the threshold voltage of the memory cell can be suppressed.

### Third Embodiment

Next, a semiconductor memory device according to a third embodiment will be described using FIG. 16. FIG. 16 is a cross-sectional schematic view of the semiconductor memory device, portions shared with the first embodiment (FIG. 6) are assigned with identical reference symbols to those of the first embodiment, and a detailed description of such portions will be omitted.

As shown in FIG. 16, the third embodiment has a configuration in which the silicide layer 30 is formed on the entire surface of the floating gate 24 and the thickness of the silicide layer at the tip end is larger than that at a base end (substrate 20 side). In order to obtain said configuration, it is only required, for example, that in the step of forming the metal layer 32 of FIG. 11, the thickness of the metal layer is selectively made larger at the tip end of the floating gate 24 by a method such as sputtering.

The electric field in the floating gate 24 is concentrated at the tip end facing the gate electrode 34. Therefore, by making the thickness of the silicide layer 30 at the tip end of the floating gate 24 large, a width of a trapping portion (reference symbol 30) in the band structure shown in FIG. 7 can be broadened and it can be made more difficult for electrons to leak out. As a result, leakage of electrons can be further suppressed compared to in the first embodiment.

As described above, due to the semiconductor memory device according to the third embodiment, it is made possible to further suppress leaking of electrons from the floating gate 24 via the inter-layer insulating film 26. As a result, lowering of the threshold voltage of the memory cell can be further suppressed.

As shown in FIG. 6 and so on, the first through third embodiments described an example where the floating gate 24 has a tapered shape directed toward the opposite side to the substrate 20. In the floating gate 24 having such a shape, it is easy for concentration of the electric field to occur at the tip end, hence it is particularly preferred for leakage of electrons to be prevented by the configuration mentioned in the first through third embodiments. However, the shape of the floating gate is not limited to such a tapered shape, and the configuration described in the first through third embodiments may be applied to floating gates of various shapes.

### Other Embodiments

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor memory device, comprising:
a floating gate formed on a substrate via a tunnel insulating film;
a gate electrode formed in a region including a region above the floating gate; and
an inter-layer insulating film formed between the floating gate and the gate electrode, above and on aside of the floating gate,
at least a part of a surface of the floating gate exposed to an inter-layer insulating film side having a silicide layer formed thereon.

2. The semiconductor memory device according to claim 1, wherein
the silicide layer is formed on at least a region of the surface of the floating gate that faces the gate electrode.

3. The semiconductor memory device according to claim 1, wherein
the silicide layer is formed on an entire surface of the floating gate exposed to the inter-layer insulating film side.

4. The semiconductor memory device according to claim 3, wherein
a thickness of the silicide layer at a tip end of the floating gate is larger than a thickness of the silicide layer at a base end thereof, the tip end being an opposite side to a substrate side of the floating gate, and the base end being the substrate side of the floating gate.

5. The semiconductor memory device according to claim 1, wherein
the floating gate has a shape that reduces from a base end positioned on a substrate side toward a tip end on an opposite side.

6. The semiconductor memory device according to claim 1, wherein
the floating gate at a tip end thereof includes therein a region which is not silicided.

7. The semiconductor memory device according to claim 1, wherein
a thickness of the silicide layer is 5 nm or less.

8. The semiconductor memory device according to claim 1, wherein
the silicide layer includes a compound of at least one of ruthenium, nickel, titanium, tungsten, cobalt, and platinum.

9. A method of manufacturing a semiconductor memory device, comprising:
stacking a tunnel insulating film and a floating gate on a substrate;
penetrating the floating gate and the tunnel insulating film, and forming an STI (shallow trench isolation) that reaches to inside of the substrate;
etching a part of the STI and exposing at least a part of a side surface of the floating gate;
forming a silicide layer in a region including a surface of the floating gate;
forming an inter-layer insulating film on the silicide layer and above and to a side of the floating gate; and
forming a gate electrode in a region including above the floating gate on the inter-layer insulating film.

10. The method of manufacturing a semiconductor memory device according to claim 9, wherein
in forming the silicide layer, the silicide layer is formed on at least a region of the surface of the floating gate that faces the gate electrode.

11. The method of manufacturing a semiconductor memory device according to claim 9, wherein
in forming the silicide layer, the silicide layer is formed on an entire surface of the floating gate exposed to an inter-layer insulating film side.

12. The method of manufacturing a semiconductor memory device according to claim 11, wherein
in forming the silicide layer, the silicide layer is formed such that a thickness of the silicide layer at a tip end on an opposite side to a substrate side of the floating gate is larger than a thickness of the silicide layer at a base end on the substrate side of the floating gate.

13. The method of manufacturing a semiconductor memory device according to claim 9, wherein
forming the silicide layer includes:
forming a metal layer in the region including the surface of the floating gate; and
reacting the surface of the floating gate with the metal layer to perform siliciding.

14. The method of manufacturing a semiconductor memory device according to claim 13, wherein
forming the metal layer includes employing sputtering to form the metal layer selectively on the surface of the floating gate.

15. The method of manufacturing a semiconductor memory device according to claim 9, wherein
forming the silicide layer is conducted such that a thickness of the silicide layer is 5 nm or less.

16. The method of manufacturing a semiconductor memory device according to claim 9, wherein
forming the silicide layer is conducted such that the silicide layer includes a compound of at least one of ruthenium, nickel, titanium, tungsten, cobalt, and platinum.
